(19) United States
(12) Patent Application Publication
(10) Pub. No.: US 2025/0248265 A1
(43) Pub. Date: Jul. 31, 2025

(54) FOLDABLE DISPLAY DEVICE

(71) Applicant: LG Display Co., Ltd., Seoul (KR)

(72) Inventor: SeungJae BAEK, Paju-si (KR)

(73) Assignee: LG Display Co., Ltd., Seoul (KR)

(21) Appl. No.: 18/793,484

(22) Filed: Aug. 2, 2024

(30) Foreign Application Priority Data
Jan. 29, 2024 (KR) 10-2024-0013036

(51) Int. Cl. G06F 3/0354; G06F 3/038; H10K 59/40; H10K 59/80; H10K 102/00

(52) U.S. Cl. CPC H10K 59/40; G06F 3/03547; H10K 59/873; G06F 3/038; H10K 2102/311

(57) ABSTRACT

In a foldable display device, a base substrate includes an active area, a non-active area surrounding the active area, with pads being disposed in one or both side portions thereof, and a folding area overlapping a portion of the active area and the non-active area. A light-emitting element is disposed in the active area of the base substrate. A cover window is disposed on the light-emitting element. The light-emitting element and the cover window disposed in the folding area extend to the non-active area to support the pads.

### CROSS-REFERENCE TO RELATED APPLICATION

This application claims priority to Korean Patent Application No. 10-2024-0013036, filed in the Republic of Korea on Jan. 29, 2024, which is hereby expressly incorporated by reference into the present application.

### BACKGROUND

### Technical Field

Example embodiments of the present disclosure relate to a display device, and more particularly, for example, without limitation, to a foldable display device.

### Discussion of the Related Art

With the entry into the information age, the display field that visually expresses electrical information signals has rapidly developed. In response, various display devices having excellent performance, such as thinness, light weight, and low power consumption, have been developed.

Specific examples of such display devices can include liquid crystal display (LCD) devices, plasma display panel (PDP) devices, field emission display (FED) devices, an electro-wetting display (EWD), organic light-emitting display (OLED) devices, quantum dot light emitting display and the like.

Recently, flexible display devices fabricated using a flexible material such as plastic (instead of a conventional inflexible glass substrate) to maintain display performance even when the display device is bent like paper, are rapidly emerging as next-generation display devices. In addition, foldable display devices having a large surface area have been developed and commercialized for commercial purposes and consumer desires.

The description provided in the background section should not be assumed to be prior art merely because it is mentioned in or associated with the background section. The background section can include information that describes one or more aspects of the subject technology.

### SUMMARY OF THE DISCLOSURE

However, the inventors of the present application have found that, as foldable display devices become larger, the length of the data lines can also become longer, thereby increasing data resistance. In particular, portrait oriented foldable display devices having a long aspect ratio in the vertical direction suffer from a greater increase in data resistance.

To solve or address the data line problem described above or other limitations associated with the related art, the inventors of the present disclosure have invented a landscape oriented foldable display device having a long aspect ratio in the horizontal direction.

The landscape oriented foldable display device may include a folding area having folding axis formed in the longitudinal direction and non-folding areas provided on both sides of the folding area, in which pads can be provided at ends of the folding area. That is, the pads can be disposed in a non-active area of the folding area that does not display an image. In addition, the pads can be covered with a resin to mitigate or prevent moisture permeation into the pads in the folding area.

However, in the folding area, the resin can be lifted or dislodged due to continuous stress caused by the bending or recovery of the display panel. This can lead to limitations such as reduced moisture resistance and cracking of the pads.

Accordingly, the inventors have invented a foldable display device able to mitigate or prevent moisture permeation without a resin by configuring the components of the display panel so that the ends of the components cover the pads disposed in the folding area.

Example embodiments of the present disclosure can provide a foldable display device in which the respective components of the display panel disposed in the folding area extend from an active area to the non-active area to cover the pads, thereby solving or addressing the problems of cracking and moisture permeation of the pads due to lifting of the resin.

Example embodiments of the present disclosure can provide a flexible display device that can be realized as a unified product in which parts are simplified and unified because the resin can be omitted.

Example embodiments of the present disclosure can provide a flexible display device in which a neutral plane occurring during bending of the folding area can be maintained constantly by positioning the ends of the respective components of the display panel in line so that no stepped portion is formed.

Example embodiments of the present disclosure can provide a foldable display device having a structure capable of minimizing damage to the folding area by evenly distributing the stress acting on the respective components during bending or recovery by forming the neutral plane of the folding area to be centered on the display panel.

Example embodiments of the present disclosure can provide a foldable display device including: a base substrate including an active area, a non-active area surrounding the active area, with a plurality of pads being disposed in one or both side portions thereof, and a folding area overlapping a portion of the active area and the non-active area; a light-emitting element disposed in the active area of the base substrate; and a cover window disposed on the light-emitting element, wherein the light-emitting element and the cover window disposed in the folding area extend to the non-active area to support the pads.

Example embodiments of the present disclosure can provide a foldable display device including: a base substrate including an active area, a non-active area surrounding the active area, with a plurality of pads being disposed in one or both side portions thereof, and a folding area overlapping a portion of the active area and the non-active area; a thin-film transistor layer disposed on the base a light-emitting element disposed on the thin-film transistor layer; an adhesive layer disposed on the light-emitting element; a touch panel disposed on the adhesive layer; a polarizer disposed on the touch panel; and a cover window disposed on the light-emitting element, wherein ends of the thin-film transistor layer, the light-emitting element, the adhesive layer, the touch panel, the polarizer, and the cover window located in the folding area are arranged in line so that no stepped portion is present

According to example embodiments of the present disclosure, in the foldable display device, the respective components of the display panel disposed in the folding area can extend from an active area to the non-active area to cover the pads, thereby solving the problems of cracking and moisture permeation of the pads due to lifting of the resin.

According to example embodiments of the present disclosure, the flexible display device can be realized as a unified product in which parts are simplified and unified because the resin can be omitted.

According to example embodiments of the present disclosure, in the flexible display device, a neutral plane occurring during bending of the folding area can be maintained constantly by positioning the ends of the respective components of the display panel in line so that no stepped portion is formed.

According to example embodiments of the present disclosure, the flexible display device has a structure capable of minimizing damage to the folding area by evenly distributing the stress acting on the respective components during bending or recovery by forming the neutral plane of the folding area to be centered on the display panel.

It is to be understood that both the foregoing general description and the following detailed description are exemplary and explanatory and are intended to provide further explanation of the inventive concepts as claimed.

### BRIEF DESCRIPTION OF THE DRAWINGS

The accompanying drawings, which are included to provide a further understanding of the disclosure and are incorporated in and constitute a part of this application, illustrate embodiments of the disclosure and together with the description serve to explain the principle of the disclosure.

The above and other objectives, features, and advantages of the present disclosure will be more clearly understood from the following detailed description, taken in conjunction with the accompanying drawings, in which:

FIG. 1 illustrates a system configuration of a foldable display device according to example embodiments of the present disclosure;

FIG. 2 is a plan view illustrating a display device according to example embodiments of the present disclosure;

FIG. 3 is a cross-sectional view illustrating the display device taken along the line A-A′ of FIG. 2;

FIG. 4 is a cross-sectional view illustrating the display device taken along the line B-B′ of FIG. 2;

FIG. 5 illustrates the neutral plane in FIG. 3 illustrating the display device taken along the line A-A′ of FIG. 2; and

FIG. 6 illustrates the neutral plane in FIG. 4 illustrating the display device taken along the line B-B′ of FIG. 2.

Throughout the drawings and the detailed description, unless otherwise described, the same drawing reference numerals should be understood to refer to the same elements, features, and structures. The relative size and depiction of these elements can be exaggerated for clarity, illustration, and convenience.

### DETAILED DESCRIPTION OF THE EMBODIMENTS

In the following description of examples or embodiments of the present disclosure, reference will be made to the accompanying drawings in which it is shown by way of illustration specific examples or embodiments that can be implemented, and in which the same reference numerals and signs can be used to designate the same or like components even when they are shown in different accompanying drawings from one another. Further, in the following description of examples or embodiments of the present disclosure, detailed descriptions of well-known functions and components incorporated herein will be omitted when it is determined that the description can make the subject matter in some embodiments of the present disclosure rather unclear. Names of the respective elements used in the following explanations can be selected only for convenience of writing the specification and can be thus different from those used in actual products. The terms such as “including”, “having”, “containing”, “constituting” “made up of”, and “formed of” used herein are generally intended to allow other components to be added unless the terms are used with the term “only”. As used herein, singular forms are intended to include plural forms unless the context clearly indicates otherwise.

Terms, such as “first”, “second”, “A”, “B”, “(A)”, or “(B)” can be used herein to describe elements of the present disclosure. Each of these terms is not used to define essence, order, sequence, or number of elements etc., but is used merely to distinguish the corresponding element from other elements.

The shapes, sizes, dimensions (e.g., length, width, height, thickness, radius, diameter, area, etc.), ratios, angles, number of elements, ratios, angles, numbers, and the like, which are illustrated in the drawings to describe various example embodiments of the present disclosure are merely given by way of example. Therefore, the present disclosure is not limited to the illustrations in the drawings. Any implementation described herein as an “example” is not necessarily to be construed as preferred or advantageous over other implementations.

The word “exemplary” is used to mean serving as an example or illustration. Embodiments are example embodiments. Aspects are example aspects. Any implementation described herein as an “example” is not necessarily to “embodiments,” “examples,” “aspects,” and the like should not be construed as preferred or advantageous over other implementations. An embodiment, an example, an example embodiment, an aspect, or the like can refer to one or more embodiments, one or more examples, one or more example embodiments, one or more aspects, or the like, unless stated otherwise. Further, the term “can” encompasses all the meanings of the term “may.”

When it is mentioned that a first element “is connected or coupled to”, “contacts or overlaps” etc. a second element, it should be interpreted that, not only can the first element “be directly connected or coupled to” or “directly contact or overlap” the second element, but a third element can also be “interposed” between the first and second elements, or the first and second elements can “be connected or coupled to”, “contact or overlap”, etc. each other via a fourth element. Here, the second element can be included in at least one of two or more elements that “are connected or coupled to”, “contact or overlap”, etc. each other.

When time relative terms, such as “after”, “subsequent to”, “next”, “before”, and the like, are used to describe processes or operations of elements or configurations, or flows or steps in operating, processing, manufacturing methods, these terms can be used describe non-consecutive or non-sequential processes or operations unless the term “directly” or “immediately” is used together.

The terms, such as “below,” “lower,” “above,” “upper” and the like, can be used herein to describe a relationship between element(s) as illustrated in the drawings. It will be understood that the terms are spatially relative and based on the orientation depicted in the drawings.

In addition, when any dimensions, relative sizes etc. are mentioned, it should be considered that numerical values for an elements or features, or corresponding information (e.g., level, range, etc.) include a tolerance or error range that can be caused by various factors (e.g., process factors, internal or external impact, noise, etc.) even when a relevant description is not specified.

Features of various embodiments of the present disclosure can be partially or overall coupled to or combined with each other, and can be variously inter-operated with each other and driven technically as those skilled in the art can sufficiently understand. Embodiments of the present disclosure e can be carried out independently from each other, or can be carried out together in co-dependent relationship.

The term “or” means “inclusive or” rather than “exclusive or.” That is, unless otherwise stated or clear from the context, the expression that “x uses a or b” means any one of natural inclusive permutations. For example, “a or b” can mean “a,” “b,” or “a and b.” For example, “a, b or c” can mean “a,” “b,” “c,” “a and b,” “b and c,” “a and c,” or “a, b and c.”

The phase that an element (e.g., layer, film, region, component, section, or the like) is “provided in,” “disposed in,” or the like in another element can be understood as that at least a portion of the element is provided in, disposed in, or the like in another element, or that the entirety of the element is provided in, disposed in, or the like in another element. The phase that an element (e.g., layer, film, region, component, section, or the like) “contacts,” “overlaps,” or the like with another element can be understood as that at least a portion of the element contacts, overlaps, or the like with a least a portion of another element, that the entirety of the element contacts, overlaps, or the like with a least a portion of another element, or that at least a portion of the element contacts, overlaps, or the like with the entirety of another element.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning for example consistent with their meaning in the context of the relevant art and should not be interpreted in an idealized or overly formal sense unless expressly so defined herein. For example, the term “part” or “unit” can apply, for example, to a separate circuit or structure, an integrated circuit, a computational block of a circuit device, or any structure configured to perform a described function as should be understood to one of ordinary skill in the art.

Hereinafter, a variety of embodiments of the present disclosure will be described in detail with reference to the accompanying drawings. All the components of each display device or apparatus according to all embodiments of the present disclosure are operatively coupled and configured.

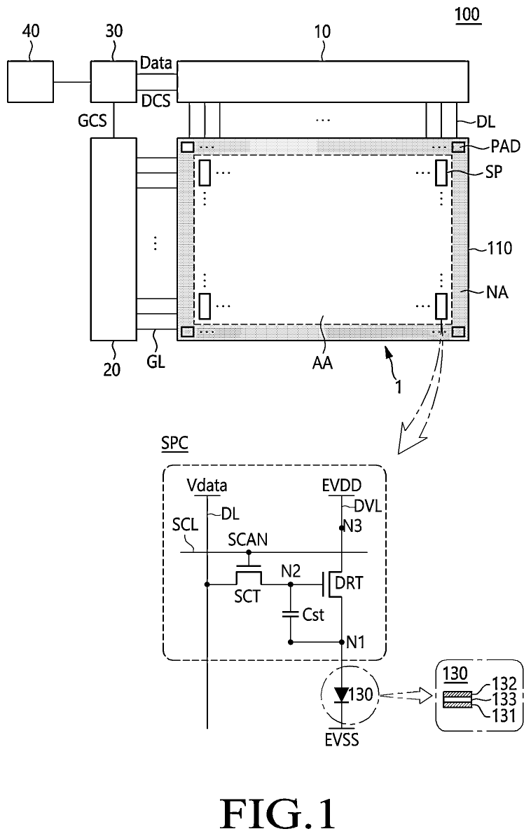

FIG. 1 illustrates a system configuration of a foldable display device according to example embodiments of the present disclosure.

Referring to FIG. 1, a display driver system of a foldable display device 100 according to example embodiments of the present disclosure can include a display panel 1 and a display driving circuit for driving the display panel 1.

The display panel 1 can include an active area (or display area) AA in which images are displayed and a non-active area (or non-display area) NA in which no images are displayed. As an example, the non-active area NA can partially or fully surround the active area AA, without being limited thereto. The display panel 1 can include a plurality of subpixels SP disposed on a base substrate 110 for displaying images.

The display panel 1 can include a plurality of signal lines disposed on the base substrate 110. For example, the signal lines can include data lines DL, gate lines GL, driving voltage lines DVL, and the like.

The respective data lines DL can be arranged to extend in a first direction (e.g., a column or row direction), and the respective gate lines GL can be arranged to extend in a direction intersecting the first direction.

The display driving circuit can include a data driver circuit 10 and a gate driver circuit 20, and can further include a controller 30 for controlling the data driver circuit 10 and the gate drive circuit 20.

The data driver circuit 10 can output data signals (also referred to as data voltages) corresponding to image (or video) signals to the data lines DL. The gate driver circuit 20 can generate gate signals GCS and output the gate signals GCS to the gate lines GL. The controller 30 can convert input image data coming from, for example, an external host 40 according to the format of data signals DCS used by the data driver circuit 10 and supply the converted image data to the data driver circuit 10.

The data driver circuit 10 can include one or more source driver integrated circuits. For example, each of the source driver integrated circuits can be connected to the display panel 1 by a tape-automated bonding (TAB) method, connected to a pad PAD on the display panel 1 by a chip-on-glass (COG) or chip-on-panel (COP) method, or implemented by a chip-on-film (COF) method or a tape carrier package (TCP) method to be connected to the display panel 1, without being limited thereto. As an example, each of the source driver integrated circuits can be disposed on the display panel or distributed in the active area AA, without being limited thereto.

The gate driver circuit 20 can be connected to the display panel 1 by a TAB method, connected to the pads PAD of the display panel 1 by a COG or COP method, connected to the display panel 1 by a COF method, or provided in a non-active area NA of the display panel 1 by a gate-in-panel (GIP) method, or can be distributed in the active area AA, without being limited thereto.

As an example, a GIP circuit part can be disposed on at least one side (e.g., the left and right sides) of the non-active area NA in FIG. 1, and the pads PAD connected to external circuits and an external power source can be disposed on at least one side (e.g., the top and bottom sides) of the non-active area NA, without being limited thereto. Here, the non-active area NA in which the pads PAD are disposed can be defined as a pad area.

Referring to FIG. 1, in the foldable display device 100 according to example embodiments of the present disclosure, each of the subpixels SP can include a light-emitting element 130 and a pixel driver circuit SPC for driving the light-emitting element 130, and the pixel driver circuit SPC can include a driving transistor DRT, a scanning transistor SCT, and a storage capacitor Cst.

The driving transistor DRT can drive the light-emitting element 130 by controlling current flowing to the light-emitting element 130. The scanning transistor SCT can transfer a data voltage Vdata to a second node N2 of the driving transistor DRT, which is a gate node. The storage capacitor Cst can be configured to maintain a voltage for a predetermined period of time.

The light-emitting element 130 can include a first electrode 131, a second electrode 132, and a light-emitting layer 133 located between the first electrode 131 and the second electrode 132. The first electrode 131 can be a pixel electrode involved in forming the light-emitting element 130 of each of the subpixels SP, and can be electrically connected to a first node N1 of the driving transistor DRT. The second electrode 132 can be a common electrode involved in forming the light-emitting elements 130 of all of the subpixels SP, and a base voltage EVSS can be applied to the second electrode 132.

For example, the light-emitting element 130 can be an organic light-emitting diode OLED, an inorganic light-emitting diode (LED), a quantum dot light-emitting element, which is a self-emitting semiconductor crystal, or the like.

The driving transistor DRT can be a transistor for driving the light-emitting element 130, and can include the first node N1, the second node N2, and a third node N3. The first node N1 can be a source or drain node, and can be electrically connected to the first electrode of the light-emitting element 130. The second node N2 can be a gate node, and can be electrically coupled to a source or drain node of the scanning transistor SCT. The third node N3 can be a drain or source node, and can be electrically connected to a driving voltage line DVL through which a driving voltage EVDD is supplied. In the following, for the sake of brevity, a situation in which the first node N1 is a source node and the third node N3 is a drain node will be described as an example.

The scanning transistor SCT can switch the connection between the data line DL and the second node N2 of the driving transistor DRT. The scanning transistor SCT can control the connection between the second node N2 of the driving transistor DRT and a corresponding data line DL of the data lines DL in response to a scan signal SCAN supplied from a scan line SCL, which is a type of gate line GL.

The storage capacitor Cst can be provided between the first node N1 and the second node N2 of the driving transistor DRT.

The structure of subpixel SP shown in FIG. 1 is for illustrative purposes only, and can further include one or more transistors or one or more capacitors. In another example, the respective subpixels can have the same structure, or at least some of the subpixels can have different structures. Each of the driving transistor DRT and the scanning transistor SCT can be an n-type transistor or a p-type transistor.

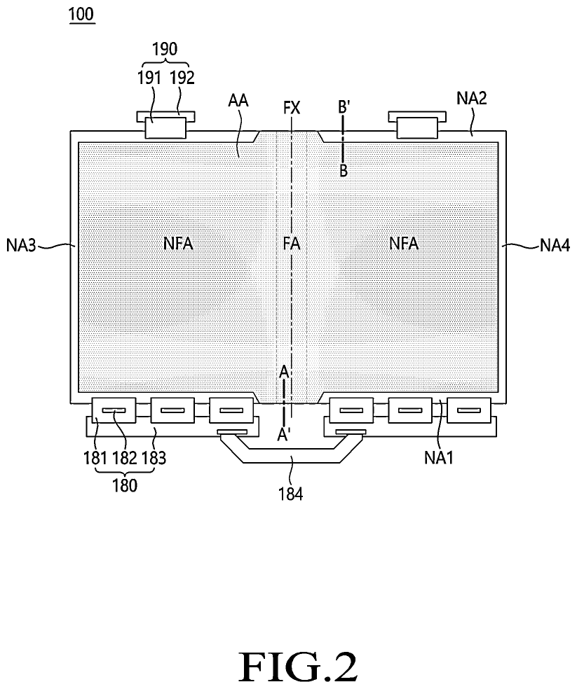

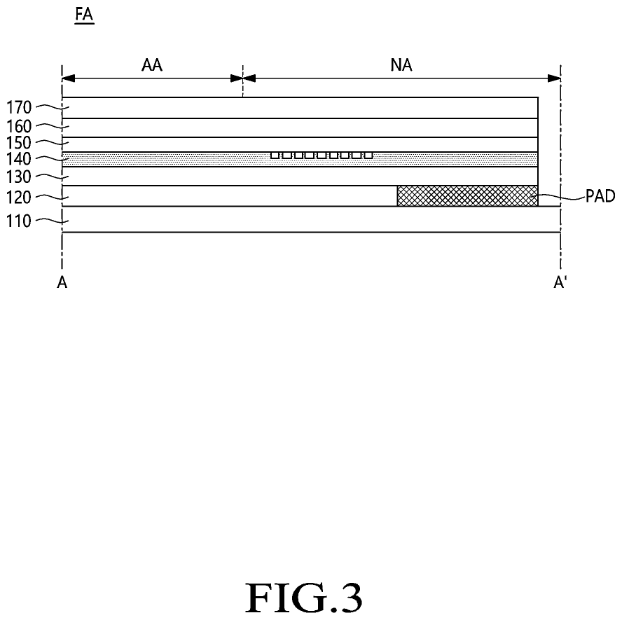

FIG. 2 is a plan view illustrating a display device according to example embodiments of the present disclosure, and FIG. 3 is a cross-sectional view illustrating the display device taken along the line A-A′ of FIG. 2.

Referring to FIGS. 2 and 3, a foldable display device 100 can include a base substrate 110, a thin-film transistor layer 120, a light-emitting element 130, an adhesive layer 140, a touch panel 150, a polarizer 160, and a cover window 170. Embodiments are not limited thereto. As an example, at least one of the above-mentioned components (e.g., the adhesive layer 140, the touch panel 150, or the polarizer 160, etc.) can be omitted, and/or one or more additional components can be further included.

The base substrate 110 is intended to support various components of the foldable display device 100, and can be made of an insulating material such as glass, plastic, or polyimide (PI), without being limited thereto.

The base substrate 110 can include an active area AA, a non-active area NA, and a folding area FA. The active area AA can be an area in which images are displayed by a plurality of subpixels SP. The non-active area NA is an area in which no images are displayed, and can be located to partially or fully surround the active area AA, with a plurality of pads PAD being disposed in one or more side portions of the non-active area NA. For example, the non-active area NA can include a first non-active area NA1 provided perpendicular to the folding axis FX of the folding area FA, a second non-active area NA2 provided to face the first non-active area NA1, and a third non-active area NA3 and a fourth non-active area NA4 extending between the first non-active area NA1 and the second non-active area NA2 and provided to face each other. Embodiments are not limited thereto. As an example, at least one of the first non-active area NA1 to the fourth non-active area NA4 can be omitted, or can be bent toward a rear side of the foldable display device 100 to be at least partially invisible from the front side of foldable display device 100, without being limited thereto.

The folding area FA is formed around the folding axis FX, and can be an area overlapping a portion of the active area AA and a portion of the non-active area NA. For example, the folding area FA can be an area that bends (e.g., with a predetermined curvature or with varied curvatures) when the foldable display device 100 is folded about the folding axis FX. The area other than the folding area FA can be a non-folding area NFA (e.g., flat). For example, the non-folding area NFA can extend to both side portions of the folding area FA, and two non-folding areas NFA can be formed on both side portions of the folding area FA. Although it is illustrated in FIG. 2 that there is only one folding axis FX and one folding area FA, embodiments are not limited thereto. As an example, there could be two or more folding axes FX and two or more folding areas FA. As an example, the two or more folding axes FX can be or can be not parallel with each other. As an example, as an example, the two or more folding axes FX can be spaced apart from each other or can intersect with each other.

The thin film transistor layer 120 can be disposed in the active area AA and the non-active area NA of the base substrate 110. For example, the thin film transistor layer 120 can include data lines DL, gate lines GL, and driving transistors DRT, and the pads PAD can be disposed in the non-active area NA of the thin film transistor layer 120.

The light-emitting element 130 can be disposed over the thin-film transistor layer 120. For example, the light-emitting element 130 can be disposed only in the active area AA or can be disposed in the active area AA and a portion of the non-active area NA. In this case, the end of the light-emitting element 130 disposed in the non-active area NA can be formed so as not to overlap the pad. As an example, the light-emitting element 130 can extend from the active area AA to a previous area in which the pads PAD are disposed.

Referring to FIG. 1, the light-emitting element 130 can include a first electrode 131, a second electrode 132, and a light-emitting layer 133.

The first electrode 131 can be an anode, which can be disposed independently on each of the subpixels SP.

The first electrode 131 can be implemented as a transparent electrode made of, for example, indium tin oxide (ITO) or indium zinc oxide (IZO), or can be implemented as an opaque electrode made of, for example, aluminum (Al), copper (Cu), or nickel (Ni), without being limited thereto. In addition, the first electrode 131 can be formed by layering a transparent electrode and an opaque electrode, without being limited thereto.

The second electrode 132 can be a cathode, which can be provided in the active area AA and the non-active area NA.

The second electrode 132 can be implemented as a transparent electrode made of, for example, indium tin oxide (ITO) or indium zinc oxide (IZO), or can be implemented as an opaque electrode made of, for example, aluminum (Al), copper (Cu), or nickel (Ni), without being limited thereto. In addition, the second electrode 132 can be formed by layering a transparent electrode and an opaque electrode, without being limited thereto.

The light-emitting layer 133 can be disposed between the first electrode 131 and the second electrode 132. For example, the light-emitting layer 133 can be an organic light-emitting layer including a hole injection layer (HIL), a hole transport layer (HTL), an emission material layer (EML), an electron transfer layer (ETL), an electron injection layer (EIL), and the like. Embodiments are not limited thereto. As an example, at least one of the hole injection layer (HIL), the hole transport layer (HTL), the electron transfer layer (ETL), the electron injection layer (EIL) can be omitted, in at least some or all of the subpixels SP.

The adhesive layer 140 can be disposed over the light-emitting element 130 to bond the light-emitting element 130 and the touch panel 150. For example, the adhesive layer 140 can be provided as an optically clear adhesive (OCA), without being limited thereto. For example, the adhesive layer 140 can be provided as an optically clear adhesive (OCA) that transmits at least 97% of light but has good adhesion to be properly used as an adhesive for the foldable display device 100, without being limited thereto.

The touch panel 150 can be disposed over the adhesive layer 140 as a touch sensor to further provide the foldable display device 100 with not only an image display function but also a touch sensing function. For example, the touch panel 150 can include a plurality of touch electrodes electrically connected by a plurality of touch electrode lines. Embodiments are not limited thereto. As an example, the adhesive layer 140 and the touch panel 150 can be omitted depending on the design.

The foldable display device 100 can include a touch driving circuit to drive and sense the touch panel 150 and generate and output touch sensing data, a touch controller to detect a touch or determine a touched position using the touch sensing data, and the like.

The polarizer 160 can be disposed over the touch panel 150 to selectively transmit light and reduce the reflection of external light incident on the display panel 1. For example, the polarizer 160 can be made of a material, such as polyvinyl alcohol (PVA), polycarbonate (PC), or polymethacrylate (PMMA), without being limited thereto. As an example, the polarizer 160 can be omitted depending on the design.

The cover window 170 is for protecting the display panel 1 and can be disposed over the polarizer 160. The cover window 170 can be made of a material (e.g., a glass material, a sapphire material, a plastic material, etc.) having excellent optical properties, high strength and impact resistance, and high surface hardness, without being limited thereto. For example, the cover glass can be a thin cover glass (TCG) having a thickness of 90 μm or less, without being limited thereto. The thin cover glass having a limited thickness as described above can effectively reduce stress applied during bending.

According to an exemplary embodiment of, the light-emitting element 130, the adhesive layer 140, the touch panel 150, the polarizer 160, and the cover window 170 disposed in the folding area FA can extend to the non-active area NA to cover the pad. As an example, the pad disposed in the folding area FA can be shielded by the light-emitting element 130, the adhesive layer 140, the touch panel 150, the polarizer 160, and the cover window 170. Embodiments are not limited thereto. As an example, at least one of the light-emitting element 130, the adhesive layer 140, the touch panel 150, the polarizer 160, and the cover window 170 disposed in the folding area FA can extend to the non-active area NA to cover the pad. As an example, at least one of the light-emitting element 130, the adhesive layer 140, the touch panel 150, the polarizer 160, and the cover window 170 disposed in the folding area FA can not extend to the non-active area NA. As an example, at least one or each of the light-emitting element 130, the adhesive layer 140, the touch panel 150, the polarizer 160, and the cover window 170 disposed outside the folding area FA can extend to the non-active area NA to cover the pad. As an example, at least one or all of the light-emitting element 130, the adhesive layer 140, the touch panel 150, the polarizer 160, and the cover window 170 disposed outside the folding area FA can not extend to the non-active area NA.

Accordingly, it is possible to reduce or prevent moisture from entering the pads PAD from the folding area FA without providing a resin covering the pads PAD. In other words, previously, since the pads PAD disposed in the folding area FA are not shielded by the light-emitting element 130, the adhesive layer 140, the touch panel 150, the polarizer 160, and the cover window 170 disposed thereabove, as an example, a resin was separately provided to cover the pads PAD.

When the pads PAD are shielded through the resin in this manner, stress caused by the bending or recovery of the foldable display device 100 in the non-folding area NFA is not relevant, but in the folding area FA, the stress caused by the bending or recovery of the foldable display device 100 continuously acts on the resin, causing the phenomenon of the resin lifting. In this case, the pads PAD bonded to the resin can be cracked and damaged, and moisture can enter the gap between the display panel 1 and the resin, thereby reducing the reliability of the foldable display device 100.

In order to solve these problems, in the foldable display device 100 according to the present exemplary embodiment, moisture resistance can be improved by deleting the resin disposed in the folding area FA and covering the pads PAD with at least one of the light-emitting element 130, the adhesive layer 140, the touch panel 150, the polarizer 160, and the cover window 170 of the display panel 1.

Specifically, as an example, both sides of each of the light-emitting element 130, the adhesive layer 140, the touch panel 150, the polarizer 160, and the cover window 170 covering the pads PAD in the folding area FA can extend to the outside of the folding area FA to overlap portions of the non-folding area NFA provided on both sides of the folding area FA (see FIG. 2). This configuration can increase the area covering the pads PAD, thereby improving moisture resistance. Embodiments are not limited thereto. As an example, only one side of at least one or each of the light-emitting element 130, the adhesive layer 140, the touch panel 150, the polarizer 160, and the cover window 170 covering the pads PAD in the folding area FA can extend to the outside of the folding area FA to overlap portions of the non-folding area NFA provided on the one side of the folding area FA. As an example, at least one or each of the light-emitting element 130, the adhesive layer 140, the touch panel 150, the polarizer 160, and the cover window 170 covering the pads PAD in the folding area FA can not extend to the outside of the folding area FA on both sides of the folding area FA.

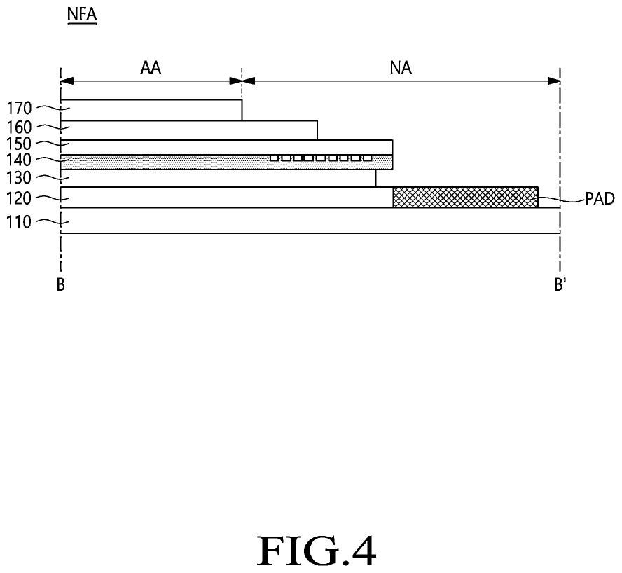

FIG. 4 is a cross-sectional view illustrating the display device taken along the line B-B′ of FIG. 2.

Referring to FIG. 4, in the foldable display device 100, the ends of the light-emitting element 130, the adhesive layer 140, the touch panel 150, the polarizer 160, and the cover window 170 located in the non-folding area NFA can each be arranged so as not to overlap the pads, that is, can be configured to cover the pads only in the folding area FA but not in the non-folding area NFA. However, the structure of the light-emitting element 130, the adhesive layer 140, the touch panel 150, the polarizer 160, and the cover window 170 located in the non-folding area NFA is not limited to this example, and can be configured to cover the pads PAD as in the folding area FA.

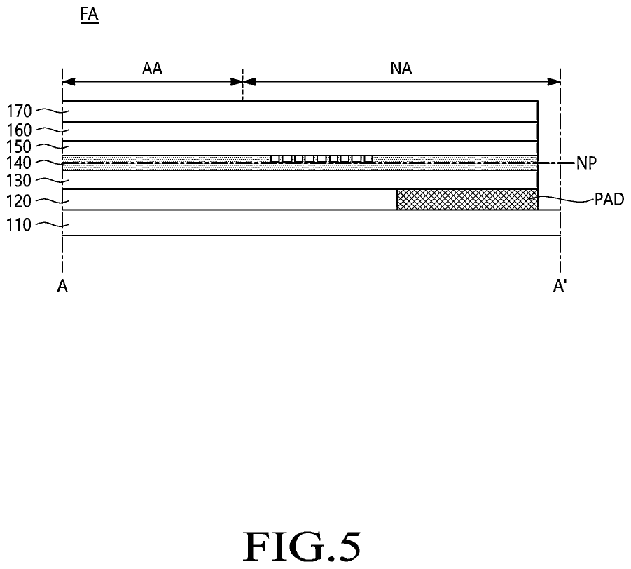

FIG. 5 illustrates the neutral plane in FIG. 3 illustrating the display device taken along the line A-A′ of FIG. 2.

As shown in FIG. 5, in the foldable display device 100 according to the present exemplary embodiment, the respective components of the display panel 1 can be arranged in line so that no stepped portion is formed at the ends of the respective components. For example, the ends of the thin-film transistor layer 120, the light-emitting element 130, the adhesive layer 140, the touch panel 150, the polarizer 160, and the cover window 170 of the display panel 1 can be arranged side by side in line with each other so that no stepped portion is provided.

Since no stepped portion is provided at an edge of the display panel 1 as described above, the neutral plane NP occurring during bending of the folding area FA can be maintained constantly. Here, the neutral plane NP means the plane at which the stress state is zero during bending. As an example, the neutral plane NP is the plane that bends while maintaining the original length thereof without being stretched or shrunk when a bending moment is applied. Embodiments are not limited thereto. As an example, a stepped portion can be provided in the ends of at least one or each of the thin-film transistor layer 120, the light-emitting element 130, the adhesive layer 140, the touch panel 150, the polarizer 160, and the cover window 170 of the display panel 1 in the folding area FA.

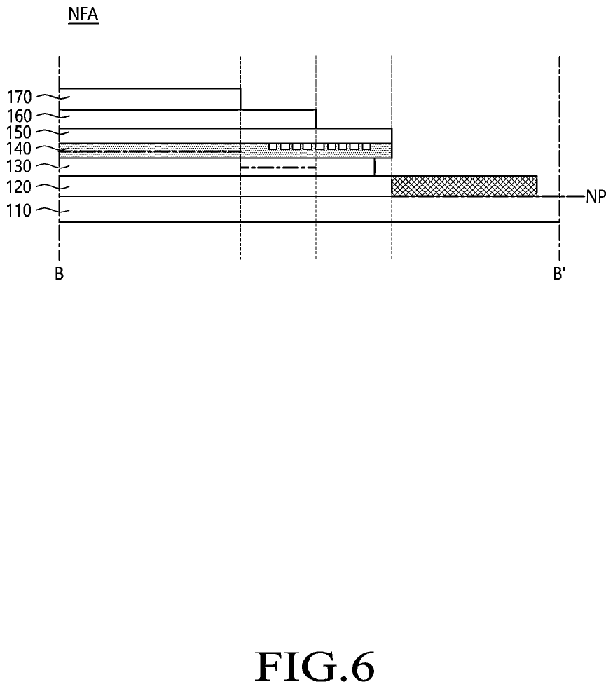

FIG. 6 illustrates the neutral planes in FIG. 4 illustrating the display device taken along the line B-B′ of FIG. 2.

Referring to FIG. 6, in the foldable display device 100, stepped portions can be provided on the components in the non-folding area NFA. When the display panel 1 is provided with the stepped portions in the non-folding area NFA in this manner, each of the neutral planes NP can be located between the corresponding ones of the components on which the stepped portions are provided.

Since the non-folding area NFA is an area in which neither bending nor recovery occurs, the presence of each neutral plane NP between the corresponding components does not affect durability. However, when each of the neutral planes NP is located between the corresponding components in the folding area FA, during bending or recovery of the folding area FA, stresses having different magnitudes can act at the boundaries of the neutral planes NP to cause distortion, thereby forming cracks in the display panel 1.

Accordingly, the foldable display device 100 according to the present exemplary embodiment is configured so that no stepped portion is formed at the ends of the respective components located in the folding area FA, as shown in FIG. 5. Accordingly, the neutral planes NP can be maintained constantly to reduce or prevent cracks from occurring during bending and recovery of the folding area FA. Embodiments are not limited thereto. As an example, no stepped portion is formed at the ends of at least one or each of the respective components located in the non-folding area NFA.

In addition, during bending, a tensile stress acts inside the neutral plane NP, while a compressive stress acts outside the neutral plane NP. In this case, the magnitude of the tensile stress or the compressive stress on the display panel 1 can be determined proportional to the distance from the neutral plane NP. Accordingly, as the distance from the neutral plane NP increases, the magnitude of the tensile stress or the compressive stress increases.

In view of the above, in the foldable display device 100 according to the present exemplary embodiment, the neutral plane occurring during bending of the folding area FA can be located in the central portion of the display panel 1. As an example, the neutral plane occurring during bending of the folding area FA can be located over the adhesive layer 140 (see FIG. 5). As an example, when the neutral plane NP is formed in the folding area FA to be located in the central portion of the display panel 1, the stress acting on the respective components during bending and recovery can be uniformly distributed to reduce or minimize damage to the folding area FA. The positions of the neutral planes NP can be determined by controlling the thicknesses of the respective components of the display panel 1. Although it is illustrated or described that the adhesive layer 140 is located in the central portion of the display panel 1, embodiments are not limited thereto. As an example, any of the thin-film transistor layer 120, the light-emitting element 130, the adhesive layer 140, the touch panel 150, and/or the polarizer 160 can be located in the central portion of the display panel 1.

The foldable display device 100 according to the present exemplary embodiment can be a landscape oriented display device having a long aspect ratio in the horizontal direction.

For example, in the landscape oriented foldable display device 100, the active area AA can be provided in the shape of a rectangle extending in a transverse direction, and the non-active area NA surrounding the active area AA can include a first non-active area NA1 arranged in a direction perpendicular to the folding axis FX of the folding area FA, a second non-active area NA2 arranged to face the first non-active area NA1, and a third non-active area NA3 and a fourth non-active area NA4 extending between the first non-active area NA1 and the second non-active area NA2 and arranged to face each other, without being limited thereto.

The pads PAD provided in the thin film transistor layer 120 can be disposed in the first non-active area NA1 and/or the second non-active area NA2. For example, the pads PAD disposed in the first non-active area NA1 can be connected to a data driver 180, and the pads PAD disposed in the second non-active area NA2 can be connected to a touch driver 190, without being limited thereto.

The data driver 180 can include a first circuit film 181, a data driver circuit 182, and a first printed circuit board (PCB) 183.

A plurality first circuit film 181 can be provided in the first non-active area NA1. Input terminals provided on predetermined sides of the respective first circuit films 181 can be attached to the first printed circuit board 183 by a film attaching process. Output terminals provided on the other sides of the respective first circuit films 181 can be attached to the pads PAD disposed in the first non-active area NA1 by a film attaching process.

The pads PAD disposed in the first non-active area NA1 are for supplying driving signals to the data lines DL, the gate lines GL, and the driving voltage lines DVL. Each of the first circuit films 181 can be implemented as a flexible circuit film, which can be bent to reduce the non-active area NA of the foldable display device 100. For example, the circuit films can be implemented as a tape carrier package (TCP) or a chip-on-film (COF), without being limited thereto.

A plurality data driver circuits 182 can be provided, and can be individually mounted on the first circuit films 181, respectively. The data driver circuits 182 can receive image data and data control signals from the controller 30, convert the image data into analog data signals in response to the data control signals, and supply the analog data signals to the respective data lines.

The first printed circuit board 183 can be connected to the corresponding first circuit films 181, and can transfer signals and power between the components of the data driver 180. For example, a plurality of first printed circuit board 183 can be provided in a number equal to the number of the non-folding areas NFA, and can be connected to each other by a thin connecting film 184, without being limited thereto. Further, signal transmission lines and various power lines for transmitting signals and power can be provided on the first printed circuit boards 183, without being limited thereto.

The touch driver 190 can include a second circuit film 191 and a second printed circuit board 192, without being limited thereto. As an example, the touch driver 190 can be integrated with the data driver circuit 182, without being limited thereto

A plurality of second circuit films 191 can be provided in the second non-active area NA2, without being limited thereto. Input terminals provided on predetermined sides of the respective second circuit films 191 can be attached to the second printed circuit board 192 by a film attaching process. Output terminals provided on the other sides of the respective second circuit films 191 can be attached to the pads PAD disposed in the second non-active area NA2 by a film attaching process. Here, the pads PAD disposed in the second non-active area NA2 are for driving the touch panel 150. As an example, each of the second circuit films 191 can be implemented as a flexible circuit film, which can be bent to reduce the non-active area NA of the foldable display device 100, without being limited thereto.

The second printed circuit board 192 can be connected to the second circuit films 191, and can supply touch drive signals to drive the touch panel 150. For example, a plurality of second printed circuit boards 192 can be disposed in the non-folding areas NFA and electrically connected by the second circuit films 191 to the pads PAD disposed in the second non-active area NA2, without being limited thereto.

The above-described exemplary embodiments of the present disclosure are briefly reviewed as follows.

According to example embodiments of the present disclosure, provided is a foldable display device including: a base substrate including an active area, a non-active area surrounding the active area, with a plurality of pads being disposed in one or both side portions thereof, and a folding area overlapping a portion of the active area and the non-active area; a light-emitting element disposed in the active area of the base substrate; and a cover window disposed over the light-emitting element, wherein the light-emitting element and the cover window disposed in the folding area extend to the non-active area to support the pads.

According to example embodiments of the present disclosure, non-folding areas can be provided on both sides of the folding area, and ends of the light-emitting element and the cover window located in the non-folding area can each be arranged so as not to overlap the pads.

According to example embodiments of the present disclosure, both side portions of the light-emitting element and the cover window covering the pads in the folding area can extend from the folding area to overlap a portion of the non-folding areas provided on both sides of the folding area.

According to example embodiments of the present disclosure, ends of the light-emitting element and the cover window can be arranged in line in the folding area so that no stepped portion is present.

According to example embodiments of the present disclosure, the foldable display device can further include: a thin-film transistor layer disposed between the base substrate and the light-emitting element; an adhesive layer disposed over the light-emitting element; a touch panel disposed over the adhesive layer; and a polarizer disposed over the touch panel.

According to example embodiments of the present disclosure, the thin-film transistor layer can be disposed over the base substrate in the active area and the non-active area, and the pads can be provided over the thin-film transistor layer in the non-active area.

According to example embodiments of the present disclosure, ends of the thin-film transistor layer, the touch panel, the adhesive layer, and the polarizer located in the folding area can extend to the non-active area to cover the pads.

According to example embodiments of the present disclosure, ends of the light-emitting element, the cover window, the thin-film transistor layer, the touch panel, the adhesive layer, and the polarizer located in the folding area can be arranged in line so that no stepped portion is present.

According to example embodiments of the present disclosure, a neutral plane occurring during bending of the folding area can be located on the adhesive layer.

According to example embodiments of the present disclosure, non-folding areas can be provided on both sides of the folding area, and ends of the touch panel, the adhesive layer, and the polarizer located in non-folding areas are each arranged so as not to overlap the pads.

According to example embodiments of the present disclosure, the active area can have a rectangular shape, the non-active area surrounding the active area can include a first non-active area arranged in a direction perpendicular to a folding axis of the folding area, a second non-active area arranged to face the first non-active area, and a third non-active area and a fourth non-active area extending between the first non-active area and the second non-active area and arranged to face each other, and the pads can be disposed in the first non-active area and the second non-active area.

According to example embodiments of the present disclosure, the pads disposed in a first non-active area of the non-active area can be connected to a data driver.

According to example embodiments of the present disclosure, the pads disposed in a second non-active area of the non-active area can be connected to a touch driver.

According to example embodiments of the present disclosure, provided is a foldable display device including: a base substrate including an active area, a non-active area surrounding the active area, with a plurality of pads being disposed in one or both side portions thereof, and a folding area overlapping a portion of the active area and the non-active area; a thin-film transistor layer disposed over the base substrate; a light-emitting element disposed over the thin-film transistor layer; an adhesive layer disposed over the light-emitting element; a touch panel disposed over the adhesive layer; a polarizer disposed over the touch panel; and a cover window disposed over the light-emitting element, wherein ends of the thin-film transistor layer, the light-emitting element, the adhesive layer, the touch panel, the polarizer, and the cover window located in the folding area are arranged in line so that no stepped portion is present.

According to example embodiments of the present disclosure, a neutral plane occurring during bending of the folding area can be located on the adhesive layer.

According to example embodiments of the present disclosure, ends of the thin-film transistor layer, the light-emitting element, the adhesive layer, the touch panel, the polarizer, and the cover window in the folding area can be disposed in the non-active area.

According to example embodiments of the present disclosure, the thin-film transistor layer can be disposed over the base substrate in the active area and the non-active area, and the pads are provided over the thin-film transistor layer in the non-active area.

According to example embodiments of the present disclosure, non-folding areas can be provided on both sides of the folding area, and ends of the light-emitting element, the adhesive layer, the touch panel, the polarizer, and the cover window located in non-folding areas can each be arranged so as not to overlap the pads.

According to example embodiments of the present disclosure, the light-emitting element, the adhesive layer, the touch panel, the polarizer, and the cover window located in the folding area can cover the pads.

According to example embodiments of the present disclosure, both side portions of the light-emitting element, the adhesive layer, the touch panel, the polarizer, and the cover window covering the pads in the folding area can extend from the folding area to overlap a portion of the non-folding areas provided on both sides of the folding area.

The above description has been presented to enable any person skilled in the art to make and use the technical idea of the present disclosure, and has been provided in the context of a particular application and its requirements. Various modifications, additions and substitutions to the described embodiments will be readily apparent to those skilled in the art, and the general principles defined herein can be applied to other embodiments and applications without departing from the spirit and scope of the present disclosure. The above description and the accompanying drawings provide an example of the technical idea of the present disclosure for illustrative purposes only. That is, the disclosed embodiments are intended to illustrate the scope of the technical idea of the present disclosure.

What is claimed is:

1. A foldable display device comprising:
a base substrate comprising an active area, a non-active area adjacent to the active area, with pads being disposed in one side portion or two side portions facing each other of the non-active area, and a folding area overlapping a portion of the active area and the non-active area;
a light-emitting element disposed in the active area of the base substrate; and
a cover window disposed on the light-emitting element,
wherein at least one of the light-emitting element and the cover window disposed in the folding area extends to the non-active area to overlap the pads.

2. The foldable display device of claim 1, wherein non-folding areas are provided on sides of the folding area, and ends of the light-emitting element and the cover window located in the non-folding areas are each arranged so as not to overlap the pads.

3. The foldable display device of claim 1, wherein one or two side portions of the light-emitting element and the cover window overlapping the pads in the folding area extend from the folding area to overlap a portion of the non-folding areas provided on one or more sides of the folding area.

4. The foldable display device of claim 1, wherein ends of the light-emitting element and the cover window are arranged in line in the folding area so that no stepped portion is present.

5. The foldable display device of claim 1, further comprising:
a thin-film transistor layer disposed between the base substrate and the light-emitting element.

6. The foldable display device of claim 5, further comprising:
an adhesive layer disposed on the light-emitting element;
a touch panel disposed on the adhesive layer; and
a polarizer disposed on the touch panel.

7. The foldable display device of claim 5, wherein the thin-film transistor layer is disposed on the base substrate in the active area and the non-active area, and the pads are provided on the thin-film transistor layer in the non-active area.

8. The foldable display device of claim 6, wherein ends of at least one of the touch panel, the adhesive layer, and the polarizer located in the folding area extend to the non-active area to cover the pads.

9. The foldable display device of claim 6, wherein ends of the light-emitting element, the cover window, the thin-film transistor layer, the touch panel, the adhesive layer, and the polarizer located in the folding area are arranged in line so that no stepped portion is present.

10. The foldable display device of claim 6, wherein a neutral plane occurring during bending of the folding area is located on the adhesive layer.

11. The foldable display device of claim 6, wherein non-folding areas are provided on sides of the folding area, and ends of the touch panel, the adhesive layer, and the polarizer located in non-folding areas are each arranged so as not to overlap the pads.

12. The foldable display device of claim 6, wherein ends of at least one of the light-emitting element, the cover window, the thin-film transistor layer, the touch panel, the adhesive layer, and the polarizer located in the non-folding area are arranged so that at least one stepped portion is present.

13. The foldable display device of claim 1, wherein the active area has a rectangular shape,
the non-active area surrounding the active area comprises a first non-active area arranged in a direction perpendicular to a folding axis of the folding area, a second non-active area arranged to face the first non-active area, and a third non-active area and a fourth non-active area extending between the first non-active area and the second non-active area and arranged to face each other, and
the pads are disposed in at least one of the first non-active area and the second non-active area.

14. The foldable display device of claim 13, further comprising a data driver, wherein the pads disposed in the first non-active area are connected to the data driver.

15. The foldable display device of claim 13, further comprising a touch driver, wherein the pads disposed in the second non-active area are connected to the touch driver.

16. The foldable display device of claim 1, wherein a neutral plane occurring during bending of the folding area is located in a central portion in a thickness direction of the foldable display device.

17. The foldable display device of claim 1, wherein the folding area is an area that bends when the foldable display device is folded about a folding axis.

18. A foldable display device comprising:
a base substrate comprising an active area, a non-active area surrounding the active area, with pads being disposed in one side portion or two side portions facing each other of the non-active area, and a folding area overlapping a portion of the active area and a portion of the non-active area;
a thin-film transistor layer disposed on the base substrate;
a light-emitting element disposed on the thin-film transistor layer;
an adhesive layer disposed on the light-emitting element;
a touch panel disposed on the adhesive layer;
a polarizer disposed on the touch panel; and
a cover window disposed on the light-emitting element,
wherein ends of the thin-film transistor layer, the light-emitting element, the adhesive layer, the touch panel, the polarizer, and the cover window located in the folding area are arranged in line so that no stepped portion is present.

19. The foldable display device of claim 18, wherein a neutral plane occurring during bending of the folding area is located on the adhesive layer.

20. The foldable display device of claim 18, wherein ends of the thin-film transistor layer, and at least one of the light-emitting element, the adhesive layer, the touch panel, the polarizer, and the cover window in the folding area are disposed in the non-active area.

21. The foldable display device of claim 18, wherein the thin-film transistor layer is disposed on the base substrate in the active area and the non-active area, and the pads are provided on the thin-film transistor layer in the non-active area.

22. The foldable display device of claim 21, wherein non-folding areas are provided on sides of the folding area, and ends of the light-emitting element, the adhesive layer, the touch panel, the polarizer, and the cover window located in non-folding areas are each arranged so as not to overlap the pads.

23. The foldable display device of claim 21, wherein at least one of the light-emitting element, the adhesive layer, the touch panel, the polarizer, and the cover window located in the folding area cover the pads.

24. The foldable display device of claim 23, wherein one or two side portions of the at least one of the light-emitting element, the adhesive layer, the touch panel, the polarizer, and the cover window covering the pads in the folding area extend from the folding area to overlap a portion of the non-folding areas provided on one or two sides of the folding area.

25. The foldable display device of claim 18, wherein the one side portion or the two side portions of the non-active area are arranged in a direction perpendicular to a folding axis of the folding area.
